(19) United States
(12) Patent Application Publication
(10) Pub. No.: US 2024/0282725 A1
(43) Pub. Date: Aug. 22, 2024

(54) POWER AMPLIFIER

(71) Applicant: Mitsubishi Electric Corporation, Tokyo (JP)

(72) Inventors: Yoshinobu SASAKI, Tokyo (JP); Katsuya KATO, Tokyo (JP); Kazuya YAMAMOTO, Tokyo (JP)

(73) Assignee: Mitsubishi Electric Corporation, Tokyo (JP)

(21) Appl. No.: 18/566,330

(22) PCT Filed: Dec. 8, 2021
(86) PCT No.: PCT/JP2021/045054

§ 371 Date: Dec. 1, 2023

(51) Int. Cl. H01L 23/66; H03F 1/56; H03F 3/60

(52) U.S. Cl. CPC H01L 23/66; H03F 1/56; H03F 3/601; H01L 2223/6611; H01L 2223/6655

(57) ABSTRACT

A FET chip (T1) includes a FET cell (CL1,CL2), a fundamental wave gate pad (GP1,G12) and a second harmonic gate pad (GP3) separated from each other, and gate wiring (GB1,GB2) connecting a gate electrode (G1,G2) of the FET cell (CL1,CL2) to the fundamental wave gate pad (GP1,G12) and the second harmonic gate pad (GP3). A pre-match chip (P1) includes a fundamental wave pre-match circuit (PA1,PA2) and a second harmonic trap circuit (PA3). A fundamental wave wire (W21,W22) connects the fundamental wave pre-match circuit (PA1,PA2) and the fundamental wave gate pad (GP1,G12). A second harmonic wire (W31,W32) connects the second harmonic trap circuit (PA3) and the second harmonic gate pad (GP3).

### FIELD

The present disclosure relates to a power amplifier.

### BACKGROUND

Since GaN has a wide band gap, GaN-based high electron mobility transistors (HEMTs) can operate at higher supply voltages than conventional GaAs-based transistors or Si-based LDMOS transistors. Recently, high-frequency power amplifiers using GaN-based HEMTs are also becoming popular in consumer fields. One of the main fields is power amplifiers to be used in mobile phone base stations. In mobile phone base stations, as typified by fifth-generation mobile communication systems (5G), an operating frequency of approximately 2-5 GHz is mainstream, and operation at a high supply voltage of 28-50 V is normally possible. Therefore, the same output power can be achieved using a transistor with a smaller gate width compared to a conventional GaAs-based or Si-based transistor. A small gate width leads to a reduction in matching loss and power distribution/synthesis loss when impedance matching to the standard impedance of 50Ω. Therefore, a power amplifier using GaN-based HEMTs can operate at higher gain and higher efficiency than an amplifier using GaAs-based or Si-based transistors.

For GaN-based HEMT power amplifier modules, Doherty amplifiers are used, which in principle provide relatively high efficiency even at an output power 6-8 dB below saturation power. The main-amplification-section final stage of a Doherty amplifier has a FET chip and a pre-match chip. The pre-match chip has formed therein a fundamental pre-match circuit and a second harmonic trap circuit that shorts the second harmonic.

The fundamental pre-match circuit and the second harmonic trap circuit are connected by wires to gate pads of the FET chip. Drawing the wires in close proximity and parallel to each other enhances the effect of mutual inductance between the wires in the 2-5 GHz band. Consequently, the impedance of the second harmonic trap circuit is inward with a largely spread-out trajectory, which poses an obstacle to improving efficiency over a wide band. To address this, one proposal is to form a coupling line in the pre-match chip to cancel out mutual coupling between the wires (for example, see PTL 1).

### CITATION LIST

### Patent Literature

[PTL 1] WO 2019/202631

### SUMMARY OF THE INVENTION

### Problem(s) to be Solved by the Invention

Normally, the pre-match chip is formed using semiconductor processes on a GaAs chip, a glass chip, or a high-resistivity Si chip. Consequently, the wiring width is normally 10 μm to 20 μm, which is narrower than the wire circumference of 60 μm to 80 μm, and the resistance is high. Since RF signals in the GHz band concentrated on the substrate-side surface of the conductor due to the skin effect, thickening the conductor does not reduce resistance much. As a result, the reflection coefficient of the second harmonic is slightly lower compared to when the inductance of the second harmonic trap circuit is achieved with wires alone. In other words, the impedance of the second harmonic trap circuit faces slightly inward, which correspondingly lowers the efficiency of the amplifier. Moreover, the chip area is increased to the extent that coupling lines are provided in the pre-match chip, which increases cost.

The present disclosure has been made to solve problems like the above, and an objective thereof is to obtain a power amplifier capable of highly efficient operation, for which costs can be reduced.

### Solution to Problem

A power amplifier according to the present disclosure includes: a FET chip including a FET cell, a fundamental wave gate pad and a second harmonic gate pad separated from each other, and gate wiring connecting a gate electrode of the FET cell to the fundamental wave gate pad and the second harmonic gate pad: a pre-match chip including a fundamental wave pre-match circuit and a second harmonic trap circuit; a fundamental wave wire connecting the fundamental wave pre-match circuit and the fundamental wave gate pad; and a second harmonic wire connecting the second harmonic trap circuit and the second harmonic gate pad.

### Advantageous Effects of Invention

In the present disclosure, dividing the gate pad into the fundamental wave gate pad and the second harmonic gate pad increases the spacing between the fundamental wave wire and the second harmonic wire, whereby mutual coupling between the fundamental and second harmonic wires can be suppressed. Thus, highly efficient operation is possible within the fundamental band. Also, since there is no need to provide a coupling line in the pre-match chip to cancel out mutual coupling between wires, the chip area can be reduced and costs can be reduced.

### BRIEF DESCRIPTION OF THE DRAWINGS

FIG. 1 is a block diagram illustrating a GaN-based HEMT power amplifier module according to Embodiment 1.

FIG. 2 is a plan view illustrating a power amplifier according to Embodiment 1.

FIG. 3 is a circuit diagram illustrating the fundamental pre-match circuit.

FIG. 4 is a circuit diagram illustrating the second harmonic trap circuit.

FIG. 5 is a diagram illustrating the trajectory of the impedance as seen from the gate end of the FET to the pre-match circuit side in Comparative Example 1.

FIG. 6 is a diagram illustrating the trajectory of the impedance as seen from the gate end of the FET to the pre-match circuit side in Comparative Example 2.

FIG. 7 is a diagram illustrating the trajectory of the impedance as seen from the gate end of the FET to the pre-match circuit side in Embodiment 1.

FIG. 8 is a plan view illustrating a modification of the power amplifier according to Embodiment 1.

FIG. 9 is a plan view illustrating a power amplifier according to Embodiment 2.

FIG. 10 is a side view illustrating the heights of the fundamental wave wires and second harmonic wires according to Embodiment 3.

### DESCRIPTION OF EMBODIMENTS

A power amplifier according to the embodiments of the present disclosure will be described with reference to the drawings. The same components will be denoted by the same symbols, and the repeated description thereof may be omitted.

### Embodiment 1

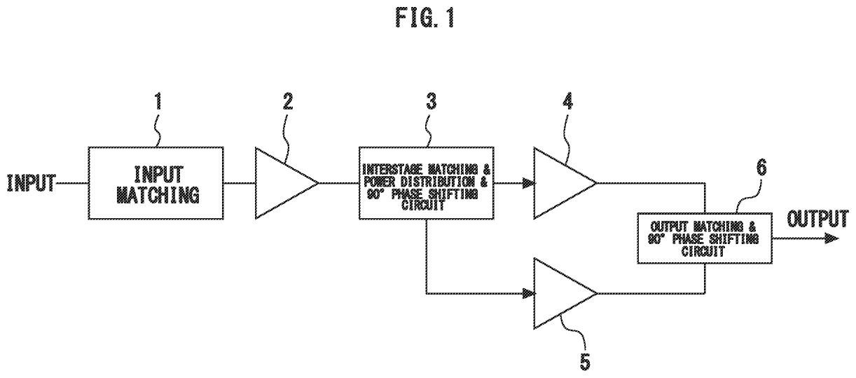

FIG. 1 is a block diagram illustrating a GaN-based HEMT power amplifier module according to Embodiment 1. The power amplifier is a Doherty amplifier. A signal inputted through an input matching section 1 is amplified by a first-stage amplification section 2. A divider circuit 3 divides the output signal of the first-stage amplification section 2 into two signals, and performs interstage matching and 90° phase shifting. The two divided signals are each amplified by a main amplifier 4 and a sub-amplifier 5. The output signals of the main amplifier 4 and the sub-amplifier 5 are synthesized with a 90° phase shift, subjected to output matching, and outputted.

Antennas with massive multi-input multi-output (MIMO) specifications for 5G mobile phone base stations are equipped with 8 vertical×8 horizontal, for a total of 64, patch antenna array typically on three sides, for example. Each patch antenna is equipped with one of the power amplifier module illustrated in FIG. 1. Thus, 64 power amplifier modules per side are mounted on the antenna back surface, and the average output power of the power amplifier modules when amplifying modulated signals is often between 5 W and 10 W per one amplifier.

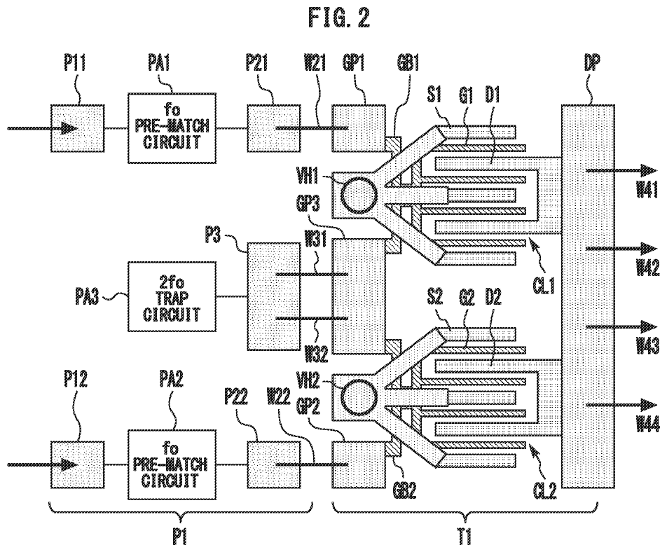

FIG. 2 is a plan view illustrating a power amplifier according to Embodiment 1. The power amplifier corresponds to the main-amplification-section final stage of the main amplifier 4 in FIG. 1. A FET chip T1 is a GaN chip, in which one or more GaN-based high electron mobility transistor (HEMT) cells are connected in parallel according to output power. For convenience, the description herein uses an example of using two FET cells CL1, CL2.

The FET cell CL1 is of the multi-finger type, with a plurality of source electrodes S1, a plurality of gate electrodes G1, and a plurality of drain electrodes D1 arranged in a comb shape. Similarly, in the FET cell CL2, a plurality of source electrodes S2, a plurality of gate electrodes G2, and a plurality of drain electrodes D2 are arranged in a comb shape. The gate electrodes G1 are connected to a fundamental wave gate pad GP1 and a second harmonic gate pad GP3 by gate wiring GB1. The gate electrodes G2 are connected to a fundamental wave gate pad GP2 and the second harmonic gate pad GP3 by gate wiring GB2.

Via holes VH1, VH2 penetrate the chip to connect the chip front surface to a back surface GND. The source electrodes S1, S2 are connected to the via holes VH1, VH2, respectively, and are at GND potential. The drain electrodes D1, D2 are connected to a drain pad DP. Output wires W41 to W44 are connected to the drain pad DP.

A pre-match chip P1 is a GaAs chip, and includes fundamental pre-match circuits PA1, PA2 and a second harmonic trap circuit PA3. The two fundamental pre-match circuits PA1, PA2 are positioned on the outside, with the second harmonic trap circuit PA3 in between. Fundamental output pads P21, P22 of the fundamental pre-match circuits PA1, PA2 are respectively connected to the fundamental wave gate pads GP1, GP2 by fundamental wave wires W21, W22. A second harmonic pad P3 of the second harmonic trap circuit PA3 is connected to the second harmonic gate pad GP3 by second harmonic wires W31, W32.

The fundamental pre-match circuits PA1, PA2 respectively accept the input of signals from input pads P11, P12, and are responsible for pre-matching to convert the input impedance of the GaN-based HEMT which, being a few (2, is much lower than the reference impedance of 50Ω, to a slightly higher impedance. The signals inputted into the pre-match circuits PA1, PA2 are then outputted from fundamental output pads P21, P22 to the gate of the GaN-based HEMT. The second harmonic trap circuit PA3 shorts the second harmonic to achieve highly efficient amplification operations within the desired band.

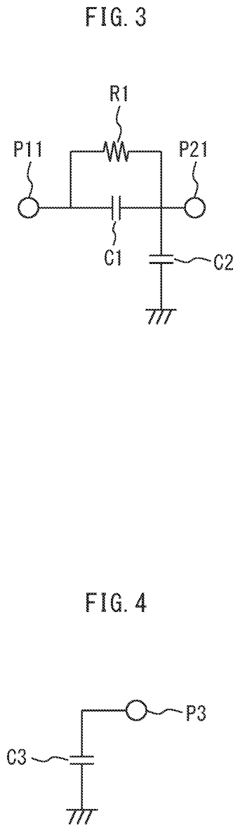

FIG. 3 is a circuit diagram illustrating the fundamental pre-match circuit. In the fundamental pre-match circuit PA1, a resistor R1 and a capacitor C1 are connected in parallel between the input P11 and the fundamental output pad P21. A capacitor C2 is connected between the fundamental output pad P21 and GND. The configuration of the fundamental pre-match circuit PA2 is similar. Here, the resistor R1 reduces the gain of the power amplifier in the band lower than the desired band and contributes to oscillation suppression.

FIG. 4 is a circuit diagram illustrating the second harmonic trap circuit. A capacitor C3 formed from MIM or the like is connected between the second harmonic pad P3 and GND. The capacitor C3 is connected to the back surface GND by a via hole penetrating the pre-match chip P1. Here, in a typical second harmonic trap circuit, a short-circuit stub is used to present a short or near-short impedance at the second harmonic frequency, as seen from the gate end of the GaN-based HEMT to the pre-match side. However, when the frequency is at or below 10 GHZ, the length of the short-circuit stub is generally longer, and the dimensions of the pre-match circuit are increased. In contrast, in the present embodiment, the second harmonic trap circuit PA3 at or below 5 GHz is configured compactly with an LC trap circuit formed from the inductance of the second harmonic wires W31, W32 and the capacitor C3.

In general, it is known that providing a second harmonic trap circuit on the input (gate) side and the output (drain) side of a transistor improves amplifier efficiency. This is referred to as class F operation. A second harmonic trap circuit on the drain side is normally effective in improving amplifier efficiency, but GaN-based HEMTs operating at 28 V to 50 V are often provided with an electrode called a source field plate between the gate and drain electrodes to improve the withstand voltage. This arrangement lightens the electric field concentrated at the gate edge and improves the breakdown voltage, but very largely increases the capacitance between drain and source. As a result, the second harmonic impedance as seen from a GaN-based HEMT to the load side is difficult to short at an appropriate frequency. Accordingly, in the present embodiment, the second harmonic trap circuit PA3 is provided on the gate side to attain an efficiency improvement. Note that to moderate the area of the GaN chip, which is still expensive, the pre-match circuit is not formed on the FET chip T1.

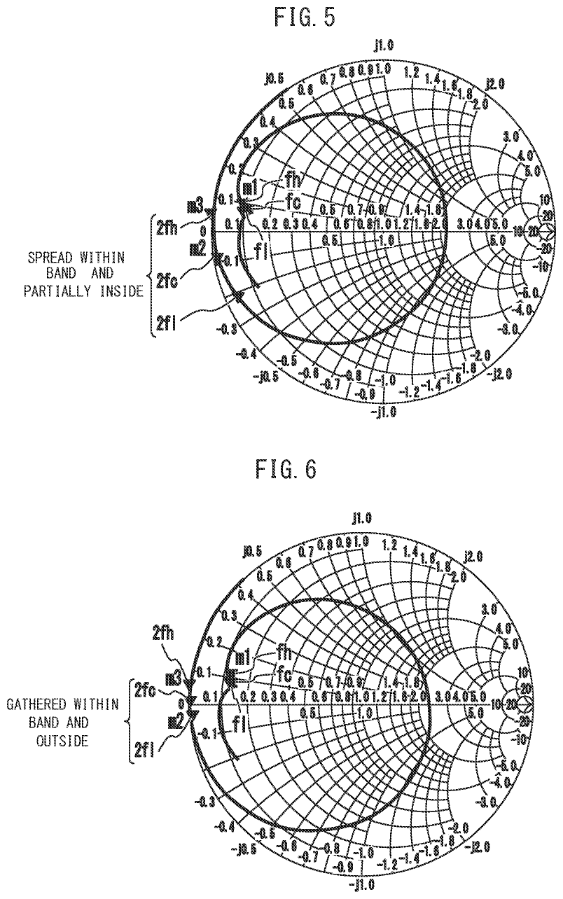

Next, the effects of the present embodiment will be described in comparison to Comparative Examples 1, 2. Comparative Example 1 is a power amplifier in which the gate pad is not divided in two pads, and the fundamental pre-match circuit and the second harmonic trap circuit are wire-connected to the same gate pad. Drawing the wires in close proximity and parallel to each other enhances the effect of mutual inductance between the wires in the 2-5 GHz band. FIG. 5 is a diagram illustrating the trajectory of the impedance as seen from the gate end of the FET to the pre-match circuit side in Comparative Example 1. The impedance of the second harmonic trap circuit is inward with a largely spread-out trajectory, which poses an obstacle to improving efficiency over a wide band.

Comparative Example 2 is a power amplifier in which a coupling line is formed in the pre-match chip to cancel out mutual coupling between the wires. FIG. 6 is a diagram illustrating the trajectory of the impedance as seen from the gate end of the FET to the pre-match circuit side in Comparative Example 2. The trajectory of the second harmonic impedance gathers on the outside and near the short-circuit point. As a result, highly efficient operation is possible over a wide band.

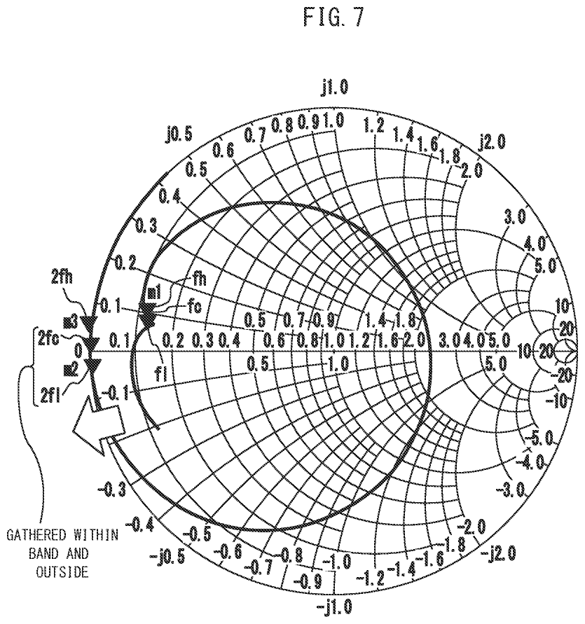

FIG. 7 is a diagram illustrating the trajectory of the impedance as seen from the gate end of the FET to the pre-match circuit side in Embodiment 1. Comparative Example 2 and Embodiment 1 both can suppress mutual coupling between the fundamental and the second harmonic to a similar degree, and thus the spread of the second harmonic impedance is comparable.

The difference between the calculated 2fo illustrated in FIGS. 6 and 7 is so slight that discerning the difference between the two is difficult, but Table 1 compares the 2fo reflection coefficients for the impedances in Comparative Example 2 and Embodiment 1. Embodiment 1 can maintain a larger second harmonic reflection coefficient. As a result, an improvement of approximately 1% pts in amplifier efficiency can be expected.

TABLE 1

| | Comparative Example 2 | Embodiment 1 |
|---|---|---|
| 2fo reflection coefficient | 0.90-0.92 | 0.94-0.95 |

In the present embodiment, dividing the gate pad into the fundamental wave gate pads GP1, GP2 and the second harmonic gate pad GP3 increases the spacing between the fundamental wave wires W21, W22 and the second harmonic wires W31, W32, whereby mutual coupling between the fundamental and second harmonic wires can be suppressed. Consequently, the second harmonic trap circuit PA3 may simply be a via hole connecting the capacitor C3 to GND and a pad mounted on the pre-match chip P1, as illustrated in FIG. 4, and thus wiring resistance can be suppressed and a large second harmonic reflection coefficient can be maintained. The spread of the second harmonic impedance corresponding to the fundamental band as seen from the gate pad of the FET chip T1 in the direction of the pre-match chip P1 on the input side can be suppressed and a large reflection coefficient can be maintained, which allows for highly efficient operation within the fundamental band. Also, since there is no need to provide a coupling line in the pre-match chip P1 to cancel out mutual coupling between wires, the chip area can be reduced and costs can be reduced.

Also, inside the FET chip T1, the gate wiring GB1 is branched in the opposite direction from the gate electrodes G1 and is connected to each of the fundamental wave gate pad GP1 and the second harmonic gate pad GP3. In other words, the gate wiring GB1, which is a bus line inside the FET, is branched into a line running to the fundamental wave gate pad GP1 side and a line running to the second harmonic gate pad GP3 side, as seen from the branch point, with the lines extending in opposite directions to each other. Similarly, inside the FET chip T1, the gate wiring GB2 is branched in a different direction from the gate electrodes G2 and is connected to each of the fundamental wave gate pad GP2 and the second harmonic gate pad GP3. Therefore, mutual coupling between the fundamental and second harmonic bus lines inside the FET chip T1 can also be suppressed.

The via holes VH1, VH2 are positioned between the fundamental wave gate pads GP1, G12 and the second harmonic gate pad GP3. With this arrangement, the spacing between the fundamental wave wire W21 and the second harmonic wire W31 is roughly 200 μm to 250 μm or more in terms of the center-to-center distance between the two. The spacing between the fundamental wave wires W21, W22 and the second harmonic wires W31, W32 is similar. With this arrangement, mutual coupling between the fundamental and second harmonic wires can be suppressed further.

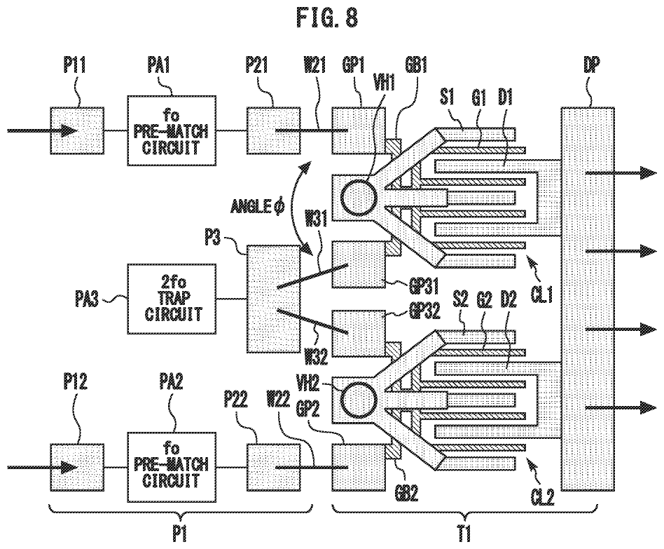

FIG. 8 is a plan view illustrating a modification of the power amplifier according to Embodiment 1. The second harmonic gate pad is divided into second harmonic gate pads GP31, G32. The spacing between the fundamental wave wires 21, W22 and the second harmonic wires W31, W32 widens farther away from the FET chip T1. For example, assuming that the wire length of the fundamental wave wires 21, W22 is approximately 300 μm, the mutual coupling is reduced by approximately 20% at an angle ϕ≈20°.

The present embodiment uses two second harmonic wires W31, W32. The configuration is not limited thereto, and the number of second harmonic wires W31, W32 may also be one, or three or more. However, to suppress the spread of the second harmonic impedance trajectory within the band, it is desirable that the inductance required to form the second harmonic trap is less than or equal to half the fundamental wave wire inductance. Consequently, if the wire lengths are assumed to be equal, it is desirable that the number of second harmonic wires W31, W32 is at least double the number of the fundamental wave wire W21 or W22.

Also, in the present embodiment, the second harmonic gate pad GP3 is positioned between the fundamental wave gate pad GP1 and the fundamental wave gate pad GP2. The second harmonic trap circuit PA3 is positioned between the fundamental pre-match circuit PA1 and the fundamental pre-match circuit PA2. In addition, the second harmonic trap circuit PA3 and the second harmonic pad P3 are common to the two FET cells CL1, CL2. Accordingly, the space for placing wires is halved compared to the case of preparing a second harmonic trap circuit for each of the two FET cells CL1, CL2. Therefore, the number of second harmonic wires W31, W32 can be increased while holding back an increase in the area of FET chip T1 and the pre-match chip P1.

### Embodiment 2

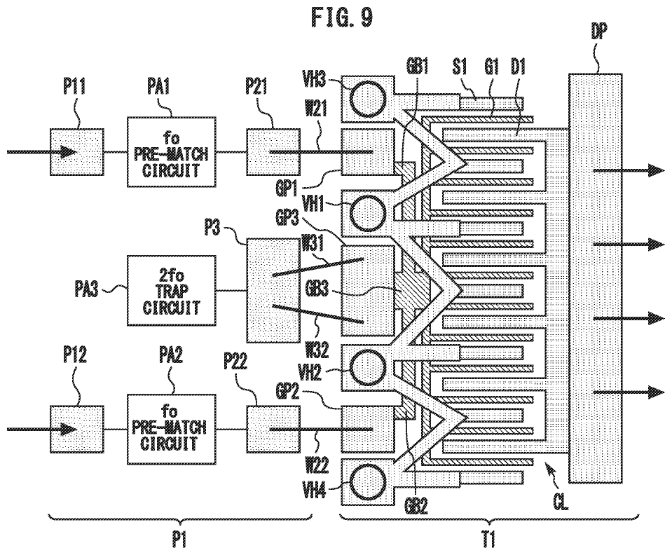

FIG. 9 is a plan view illustrating a power amplifier according to Embodiment 2. To make the size of the FET chip T1 as small as possible, the FET cells CL are connected continuously and not separated into a plurality of cells as in Embodiment 1. The actual layout is that of the present embodiment in many cases.

Via holes VH3, VH4 are positioned on the outside of the fundamental wave gate pads GP1, G12. On the other hand, the via holes VH1, VH2 are positioned respectively between the fundamental wave gate pads GP1, G12 and the second harmonic gate pad GP3, in the same way as Embodiment 1. Also, like FIG. 6, the spacing between the fundamental wave wires 21, W22 and the second harmonic wires W31, W32 widens farther away from the FET chip T1.

In Embodiment 1, the gate wiring GB1 running to the fundamental wave gate pad GP1 side and the gate wiring GB1 running to the second harmonic gate pad GP3 side are in opposite directions, and thus mutual coupling on the fundamental and second harmonic bus lines is also extremely small. In contrast, in the present embodiment, the second harmonic gate pad GP3 is positioned in the center of the FET chip T1, and the gate wirings GB1, GB2 running to the fundamental wave gate pads GP1, G12 are orthogonal to a wiring GB3 running to the second harmonic gate pad GP3, as seen from the branch point of the two. Even in this case, mutual coupling between the fundamental and second harmonic gate wirings can be suppressed adequately, a large second harmonic reflection coefficient can be maintained, and an improvement in amplifier efficiency comparable to Embodiment 1 can be expected.

### Embodiment 3

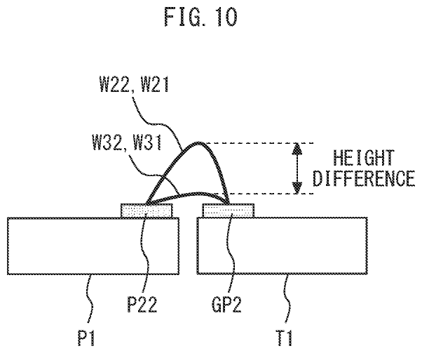

FIG. 10 is a side view illustrating the heights of the fundamental wave wires and second harmonic wires according to Embodiment 3. The degree of frequency dependence of the impedance of the wires is indicated by the spread of the trajectory illustrated in FIG. 7. Considering the sensitivity given to the circuit by the second harmonic wire length and the fundamental wave wire length, it is desirable that the second harmonic wire length is shorter than the fundamental wave wire length.

Accordingly, the second harmonic wires W31, W32 are drawn as short as possible. Additionally, the height of the fundamental wave wires W21, W22 is set higher than the height of the second harmonic wires W31, W32. The increase in height gives the fundamental wave wires W21, W22 a correspondingly longer wire length. The frequency of signals flowing through the fundamental wave wires W21, W22 is low compared to the frequency of signals flowing through the second harmonic wires W31, W32. Therefore, the effect given to fundamental matching by the increase in inductance due to the increase in the wire length of the fundamental wave wires W21, W22 can be reduced by setting the circuit constants of the pre-match circuit.

Also, by varying the height of the fundamental wave wires W21, W22 and the height of the second harmonic wires W31, W32, the distance between the fundamental wave wires W21, W22 and the second harmonic wires W31, W32 is increased compared to the case in which the heights are the same. As a result, mutual coupling between wires can be suppressed further. Compared to the case in which the heights are the same, the spread of the trajectory of the second harmonic impedance can be suppressed, and an improvement in efficiency within the desired band can be expected. Otherwise, the configuration and effects are similar to Embodiments 1, 2.

Note that although the embodiments recited above are described using an example in which the FET chip T1 is a GaN-based HEMT, it is clear that a GaAs-based HEMT or a GaAs-based FET is also possible. Also, any semiconductor process capable of forming capacitors and resistors can be applied to the formation of the fundamental pre-match circuits PA1, PA2. In particular, considering low substrate loss characteristics at high frequencies, it goes without saying that not only GaN chips and GaAs chips, for which high-resistivity substrates are available, but also silicon-on-insulator (SOI) chips, silicon-on-sapphire (SOS) chips, or integrated passive device (IPD) chips, in which semiconductor processes are applied on glass substrates, can be applied. Of course, a via-hole process connecting the surface wiring to the back surface GND in the pre-match circuit is essential to obtaining the desired RF characteristics in the 2-5 GHz band. The substrate resistivity of SOI is roughly in the range of 1 kΩcm to 10 kΩcm. Therefore, when SOI is used as the substrate on which to form the pre-match circuit, circuit losses in the high-frequency band will increase somewhat compared to a GaN-based HEMT process on a SiC substrate or a GaAs substrate with a resistivity of 1 Mcm, but costs can be kept low. IPDs using glass substrates cost as much as SOI, and also have a high resistivity of 1 Mcm. However, since glass has low thermal conductivity, circuit losses in the pre-match circuit will increase somewhat due to the higher temperature of the wiring compared to a SiC substrate or a GaAs substrate in cases where heat generated in the pre-match circuit is high.

The present disclosure is not limited to the above examples, and includes various modifications. For example, the above examples are described in detail to describe the present disclosure in an easily understood way, but the present disclosure is not necessarily limited to those provided with the entirety of the configuration described. Moreover, it is possible to replace part of the configuration of one example with the configuration of another example, and it is also possible to add to the configuration of one example the configuration of another example. It is also possible to add, remove, or replace part of the configuration of each example with another configuration.

### REFERENCE SIGNS LIST

CL,CL1,CL2 FET cell; G1,G2 gate electrode; GB1,GB2 gate wiring; GP1,G12 fundamental wave gate pad; GP3 second harmonic gate pad; P1 pre-match chip; PA1,PA2 fundamental wave pre-match circuit; PA3 second harmonic trap circuit; S1,S2 source electrode; T1 FET chip; VH1, VH2 via hole; W21,W22 fundamental wave wire; W31,W32 second harmonic wire

1. A power amplifier comprising:
a FET chip including a FET cell, a fundamental wave gate pad and a second harmonic gate pad separated from each other, and gate wiring connecting a gate electrode of the FET cell to the fundamental wave gate pad and the second harmonic gate pad;
a pre-match chip including a fundamental wave pre-match circuit and a second harmonic trap circuit;
a fundamental wave wire connecting the fundamental wave pre-match circuit and the fundamental wave gate pad; and
a second harmonic wire connecting the second harmonic trap circuit and the second harmonic gate pad,
wherein the number of second harmonic wires is at least double the number of the fundamental wave wires,
the FET cell includes first and second FET cells,
the fundamental wave gate pad includes first and second fundamental wave gate pads respectively connected to gate electrodes of the first and second FET cells,
the fundamental wave pre-match circuit includes first and second fundamental wave pre-match circuits respectively connected to the first and second fundamental wave gate pads,
the second harmonic gate pad is positioned between the first fundamental wave gate pad and the second fundamental wave gate pad,
the second harmonic trap circuit is positioned between the first fundamental wave pre-match circuit and the second fundamental wave pre-match circuit, and
the second harmonic trap circuit and the second harmonic gate pad are common to the first and second FET cells.

2. The power amplifier according to claim 1, wherein the gate wiring is branched in a different direction from the gate electrode inside the FET chip and is connected to each of the fundamental wave gate pad and the second harmonic gate pad.

3. The power amplifier according to claim 1, wherein the FET chip includes a via hole connected to a source electrode of the FET cell, and
the via hole is positioned between the fundamental wave gate pad and the second harmonic gate pad.

4. The power amplifier according to claim 1, wherein a spacing between the fundamental wave gate pad and the second harmonic gate pad is at least 200 μm, and
a spacing between the fundamental wave wire and the second harmonic wire is at least 200 μm.

5. The power amplifier according to claim 1, wherein a spacing between the fundamental wave wire and the second harmonic wire widens farther away from the FET chip.

6. (canceled)

7. (canceled)

8. The power amplifier according to claim 1, wherein a height of the fundamental wave wire is higher than a height of the second harmonic wire.
